(19) United States
(12) Patent Application Publication
(10) Pub. No.: US 2026/0276723 A1
(43) Pub. Date: Sep. 17, 2026

(54) BATTERY CELL INSPECTION METHOD AND BATTERY INSPECTION SYSTEM

(71) Applicant: SK On Co., Ltd., Seoul (KR)

(72) Inventors: Chang Gyu JANG, Daejeon (KR); Young Bee KIM, Daejeon (KR); Yu Jin LEE, Daejeon (KR)

(21) Appl. No.: 19/565,524

(22) Filed: Mar. 13, 2026

(30) Foreign Application Priority Data
Mar. 13, 2025 (KR) 10-2025-0032687

(51) Int. Cl. G01R 31/389; G01R 31/36; G01R 31/385; G01R 31/392; H01M 10/44; H01M 10/48

(52) U.S. Cl. CPC G01R 31/389; G01R 31/3648; G01R 31/3865; G01R 31/392; H01M 10/441; H01M 10/482

(57) ABSTRACT

The present disclosure relates to a battery cell inspection method for a battery inspection system which includes a pressing unit configured to press a plurality of battery cells and a charge and discharge (charge/discharge) unit configured to charge and discharge the plurality of battery cells. The battery cell inspection method includes first charging in which the plurality of battery cells are charged to a predetermined charging voltage via the charge/discharge unit, stabilizing the plurality of battery cells by suspending charging of the plurality of battery cells to the charging voltage via the charge/discharge unit for a predetermined first time period, measuring Internal Resistance (IR) of the plurality of battery cells when the plurality of battery cells are recharged via the charge/discharge unit, and determining whether each of the plurality of battery cells is defective by comparing IR measurement values with a representative value of the IR measurement values.

### CROSS-REFERENCE TO RELATED PATENT APPLICATION

The present disclosure claims priority under 35 U.S.C. § 119(a) to Korean patent application number 10-2025-0032687, filed on Mar. 13, 2025, the entire disclosure of which is incorporated herein by reference.

### BACKGROUND OF THE INVENTION

### 1. Field

Various embodiments of the present disclosure generally relate to a battery cell inspection method and a battery inspection system.

### 2. Description of the Related Art

A manufacturing process of a battery cell may include a plurality of processes. The battery cell manufacturing process may include a formation process (or activation process) for imparting electrical characteristics to assembled battery cells by charging and discharging the same and other subsequent processes. In this regard, the formation process may include a process of charging and discharging the battery cells while pressing the battery cells, and a Press Pre-Charger (PPC) that charges and discharges the battery cells while pressing the battery cells may be used in the process of charging and discharging the battery cells.

When defects occur in the battery cells during the battery cell manufacturing process, the yield of the manufacturing process may decrease. Accordingly, there is a need for determining whether the battery cells are non-defective or a battery cell inspection method during the battery cell manufacturing process.

### SUMMARY OF THE INVENTION

According to an aspect of the present disclosure, an object is to relatively reduce the time and/or cost required for a battery cell manufacturing process.

According to another aspect of the present disclosure, an object is to relatively improve the yield of the battery cell manufacturing process.

According to still another aspect of the present disclosure, an object is to determine whether battery cells are defective in a formation process (e.g., Press Pre-Charger (PPC) process) for imparting electrical characteristics to assembled battery cells by charging and discharging the same during the battery cell manufacturing process.

The battery cells according to the present disclosure can be widely applied in the green technology fields such as electric vehicles, battery charging stations, energy storage systems (ESSs), and other technologies using batteries such as photovoltaics and wind power. Furthermore, the battery cells according to the present disclosure may be used for eco-friendly mobility, including electric and hybrid vehicles, to reduce air pollution and greenhouse gas emissions to prevent or mitigate climate change.

According to the present disclosure, a battery cell inspection method for a battery inspection system, which includes a pressing unit configured to press a plurality of battery cells and a charge and discharge (charge/discharge) unit configured to charge and discharge the plurality of battery cells, may include: first charging in which the plurality of battery cells are charged to a predetermined charging voltage in a first charging method via the charge/discharge unit; stabilizing the plurality of battery cells by suspending charging of the plurality of battery cells to the charging voltage via the charge/discharge unit for a predetermined first time period; measuring Internal Resistance (IR) of the plurality of battery cells when the plurality of battery cells are recharged in a second charging method via the charge/discharge unit; and determining whether each of the plurality of battery cells is defective by comparing IR measurement values with a representative value of the IR measurement values.

Determining whether each of the plurality of battery cells is defective may include determining whether the plurality of battery cells are open-circuited by calculating a difference value between the representative value and one of the IR measurement values and comparing the difference value with a predetermined reference value.

Measuring the IR of the plurality of battery cells may be performed after stabilizing the plurality of battery cells for the predetermined first time period.

The battery cell inspection method may further include moving the plurality of battery cells after determining whether each of the plurality of battery cells is defective by comparing the IR measurement values with the representative value of the IR measurement values. In moving the plurality of battery cells, the plurality of battery cells may be moved to a degassing apparatus configured to perform degassing on the plurality of battery cells.

In measuring the IR of the plurality of battery cells, the IR may be measured in a Direct Current Internal Resistance (DC-IR) method in which the IR is measured by applying a direct current via the charge/discharge unit.

The first charging method may be a Constant Current-Constant Voltage (CC-CV) charging method, and the second charging method may be a Constant Current (CC) charging method.

According to the present disclosure, a battery cell inspection method for a battery inspection system, which includes a pressing unit configured to press a plurality of battery cells and a charge and discharge (charge/discharge) unit configured to charge and discharge the plurality of battery cells, may include: stabilizing the plurality of battery cells by suspending charging of the plurality of battery cells for a predetermined first time period after charging the plurality of battery cells in a first charging method via the charge/discharge unit; stabilizing the plurality of battery cells by suspending charging of the plurality of battery cells for a predetermined second time period after charging the plurality of battery cells in a second charging method via the charge/discharge unit; measuring Internal Resistance (IR) of the plurality of battery cells when the plurality of battery cells are discharged via the charge/discharge unit; and determining whether each of the plurality of battery cells is defective by comparing IR measurement values with a representative value of the IR measurement values.

Determining whether each of the plurality of battery cells is defective may include determining whether the plurality of battery cells are open-circuited by calculating a difference value between the representative value and one of the IR measurement values and comparing the difference value with a predetermined reference value.

The first charging method may be a Constant Current (CC) charging method, and the second charging method may be a Constant Current-Constant Voltage (CC-CV) charging method.

The plurality of battery cells may be discharged after stabilizing the plurality of battery cells by suspending the charging of the plurality of battery cells for the second time period.

The plurality of battery cells may be discharged after stabilizing the plurality of battery cells by suspending the charging of the plurality of battery cells for the first time period, and before stabilizing the plurality of battery cells by suspending the charging of the plurality of battery cells for the second time period.

The battery cell inspection method may further include moving the plurality of battery cells after determining whether each of the plurality of battery cells is defective by comparing the IR measurement values with the representative value of the IR measurement values. In moving the plurality of battery cells, the plurality of battery cells may be moved to a degassing apparatus configured to perform degassing on the plurality of battery cells.

According to the present disclosure, a battery inspection system may include a charge and discharge (charge/discharge) room configured to respectively accommodate a plurality of battery cells, a plurality of channels including connection terminals electrically coupled to the plurality of battery cells, a pressing unit configured to press the plurality of channels and the plurality of battery cells in one direction, and a controller configured to control a current or a voltage applied to the plurality of battery cells via the connection terminals. The controller may measure Internal Resistance (IR) of the plurality of battery cells when the plurality of battery cells are charged or discharged via the plurality of channels.

The controller may be configured to determine whether the plurality of battery cells are defective by calculating a difference value between IR measurement values and a representative value of the IR measurement values and comparing the difference value with a predetermined reference value.

The representative value may be an average value of the IR measurement values of the plurality of battery cells.

The controller may be configured to charge the plurality of battery cells to a predetermined charging voltage in a first charging method via the plurality of channels, and charge the plurality of battery cells in a second charging method after a predetermined first time period.

The controller may measure the IR of the plurality of battery cells while the plurality of battery cells are charged in the second charging method.

The first charging method may be a Constant Current-Constant Voltage (CC-CV) charging method, and the second charging method may be a Constant Current (CC) charging method.

The controller may charge the plurality of battery cells in the second charging method, and may measure the IR of the plurality of battery cells while discharging the plurality of battery cells after a predetermined second time period.

The first charging method may be a Constant Current (CC) charging method, and the second charging method may be a Constant Current-Constant Voltage (CC-CV) charging method.

According to an embodiment of the present disclosure, the time and/or cost required for a battery cell manufacturing process may be relatively reduced.

According to another embodiment of the present disclosure, the yield of the battery cell manufacturing process may be relatively improved.

According to still another embodiment of the present disclosure, it is possible to determine whether battery cells are defective in a formation process (e.g., Press Pre-Charger (PPC) process) for imparting electrical characteristics to assembled battery cells by charging and discharging the same during the battery cell manufacturing process.

### BRIEF DESCRIPTION OF THE DRAWINGS

FIG. 1 is an example of a battery cell according to the present disclosure;

FIG. 2 is a diagram illustrating an example of a manufacturing process based on a battery manufacturing system according to the present disclosure;

FIG. 3 is a block diagram schematically illustrating an example of a battery manufacturing system including a battery inspection system according to the present disclosure;

FIG. 4 is a diagram illustrating an example of a transfer member according to the present disclosure;

FIG. 5 is a block diagram illustrating an embodiment of a battery inspection system according to the present disclosure;

FIG. 6 is a plan view illustrating an embodiment of a battery inspection system according to the present disclosure;

FIG. 7 is a plan view illustrating an embodiment of a testing operation of a battery inspection system according to the present disclosure;

FIG. 8 is a flowchart illustrating an embodiment of a battery cell inspection method according to the present disclosure;

FIG. 9 is a flowchart illustrating an example of another embodiment of a battery cell inspection method according to the present disclosure; and

FIG. 10 is a flowchart illustrating another example of another embodiment of a battery cell inspection method according to the present disclosure.

### DETAILED DESCRIPTION

Hereinafter, example embodiments of the present disclosure will be described in detail with reference to the accompanying drawings. Configurations and control methods of an apparatus described below are provided only for the purpose of illustrating embodiments of the present disclosure and are not intended to limit the scope of the present disclosure. Throughout the specification, like reference numerals refer to like components throughout the specification.

In the following description, terms such as “first,” “second,” and “third” used to modify components are used solely for the purpose of distinguishing one component from another and do not imply any order, priority, or hierarchical relationship among the components. For example, an embodiment including only a second component without a first component may also be implemented.

Unless explicitly stated otherwise in the context, singular forms used herein are intended to also include plural forms.

In the present disclosure, the terms “battery,” “secondary battery,” and “cell” are used interchangeably with the term “battery cell.”

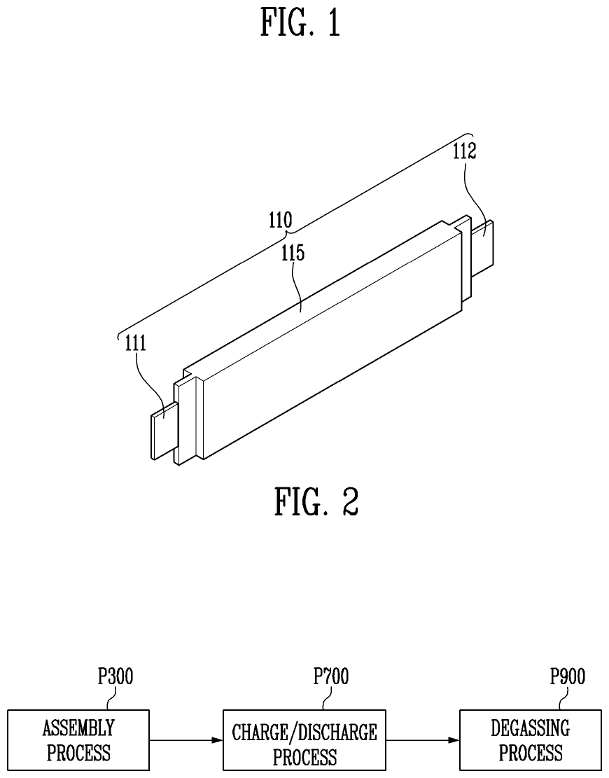

FIG. 1 is an example of a battery cell according to the present disclosure.

While FIG. 1 illustrates a pouch-type battery cell as an example of a battery cell 110 according to the present disclosure, a battery manufacturing system according to the present disclosure is also applicable to another type of a battery cell, such as a prismatic battery cell or a cylindrical battery cell.

The battery cell 110 according to the present disclosure may include a main body 115 including an electrode assembly (not shown) that generates or stores electrical energy therein, and tab portions 111 and 112 that are electrically coupled to the electrode assembly and protrude outwardly from the main body 115.

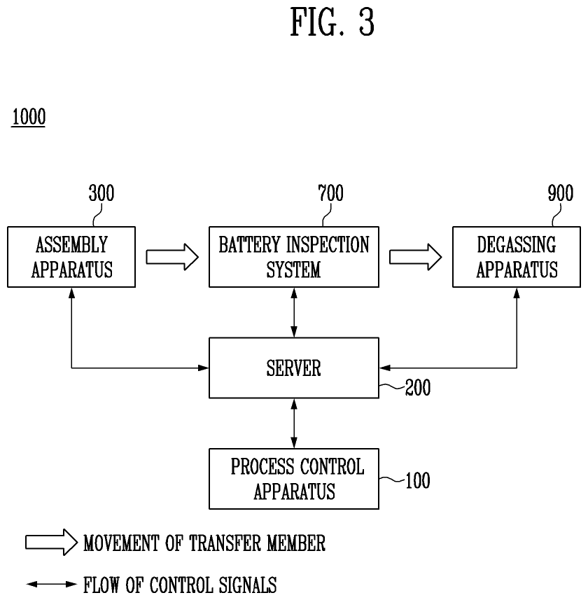

The battery cell 110 may be manufactured by a battery manufacturing system (1000, see FIG. 3). For example, the battery manufacturing system 1000 may include various processes and apparatuses for manufacturing battery cells 110 in large quantities. In this example, it is inefficient to move the battery cells 110 one by one between processes or apparatuses, and thus the battery manufacturing system 1000 may utilize a transfer member (or tray) that receives and moves a plurality of battery cells 110 at once.

FIG. 2 is a diagram illustrating an example of a manufacturing process based on a battery manufacturing system according to the present disclosure. FIG. 3 is a block diagram schematically illustrating an example of a battery manufacturing system including a battery inspection system according to the present disclosure.

Referring to FIG. 2, a battery manufacturing process includes an electrode process (not shown) for manufacturing an electrode assembly, an assembly process P300 for mechanically assembling the battery cells (110, see FIG. 1) using the manufactured electrode assembly, a formation process (or activation process) for imparting electrical characteristics to the assembled battery cells 110 by charging and discharging the same, and other subsequent processes.

The formation process may include a charge and discharge (charge/discharge) process P700 for preliminarily charging and discharging the battery cells 110, which have completed the assembly process P300, at room temperature, and a degassing process P900 for removing gases generated in the battery cells 110 during the charge/discharge process P700. Thereafter, additional charge/discharge and degassing processes may be repeatedly performed.

Referring to FIGS. 2 and 3, during the assembly process P300, the battery manufacturing system 1000 may manufacture the battery cell 110 that includes the main body (115, see FIG. 1) including an electrolyte solution in which the electrode assembly is immersed, and the tab portions (111 and 112, see FIG. 1) electrically coupled to the electrode assembly and protruding outwardly.

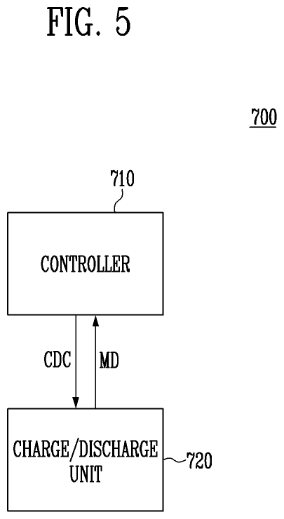

The battery manufacturing system 1000 may include a battery inspection system 700 that charges and discharges the battery cell 110 to impart electrical characteristics to the battery cell 110. While the battery inspection system 700 charges and discharges the battery cell 110, the battery inspection system 700 may determine whether the battery cell 110 is defective. For example, while the battery inspection system 700 charges and discharges the battery cell 110, the battery inspection system 700 may determine whether the battery cell 110 (or the tab portions 111 and 112) has an open circuit. A charge and discharge (charge/discharge) unit (720, see FIG. 5) of the battery inspection system 700 may be implemented as a Press Pre-Charger (PPC), but is not limited thereto.

The battery manufacturing system 1000 may include a degassing apparatus 900 that removes gases generated in the battery cell 110.

The battery manufacturing system 1000 may include an assembly apparatus 300, the battery inspection system 700, the degassing apparatus 900, and a server 200 that contains information regarding the battery cells 110 being produced. According to an embodiment, the server 200 may include data regarding Internal Resistance (IR) of the battery cell 110 and the performance of the battery cell 110 based on the IR of the battery cell 110. In this regard, the IR of the battery cell 110 may be a resistance value of the battery cell 110 (or the tab portions 111 and 112) when the battery cell 110 is charged and/or discharged via the charge/discharge unit (720, see FIG. 5).

The battery manufacturing system 1000 may include a process control apparatus 100 that controls the server 200, the assembly apparatus 300, the battery inspection system 700, and the degassing apparatus 900. The process control apparatus 100 may be installed in a control station in the battery manufacturing system 1000 and may collectively manage the server 200, the assembly apparatus 300, the battery inspection system 700, and the degassing apparatus 900. Depending on an embodiment, the process control apparatus 100 may be used to collectively refer to controllers that are individually included in each of the server 200, the assembly apparatus 300, the battery inspection system 700, and the degassing apparatus 900.

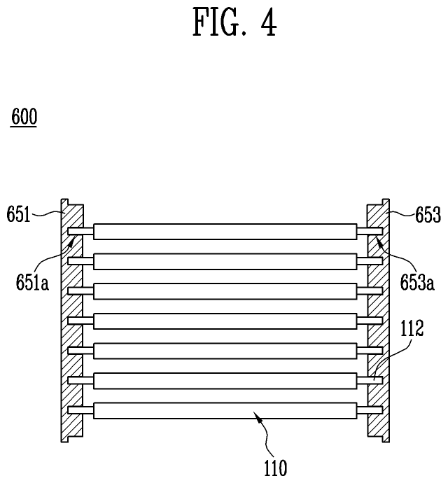

In addition, the battery manufacturing system 1000 may include a transfer member for sequentially moving the battery cells 110 between components of the battery manufacturing system 1000. For example, a transfer member according to the present disclosure may include a charge and discharge (charge/discharge) transfer member (600, see FIG. 4) that moves the battery cell 110 from the assembly apparatus 300 to the battery inspection system 700.

FIG. 4 is a diagram illustrating an example of a transfer member according to the present disclosure.

Specifically, FIG. 4 illustrates an example of the charge/discharge transfer member 600 according to the present disclosure.

FIG. 4 illustrates an example in which the plurality of battery cells 110 are received in the charge/discharge transfer member 600. The tab portions 111 and 112 of each of the plurality of battery cells 110 may be respectively inserted into and secured to a first groove 651a formed in a first grip 651 of the charge/discharge transfer member 600 and a second groove 653a formed in a second grip 653 of the charge/discharge transfer member 600. However, the present disclosure is not limited thereto.

The charge/discharge transfer member 600 may move the plurality of secured battery cells 110 to the charge/discharge unit (720, see FIG. 5) in the manner described above. For example, the charge/discharge transfer member 600 may move the plurality of battery cells 110 to a plurality of charge and discharge (charge/discharge) rooms 722.

However, a transfer member according to the present disclosure are not limited thereto. For example, the battery manufacturing system (1000, see FIG. 3) may utilize two different types of transfer members (or trays). In other words, a transfer member according to the present disclosure may be implemented in the form of a logistics transfer member that includes a transfer case provided in a box shape and capable of accommodating the plurality of battery cells 110.

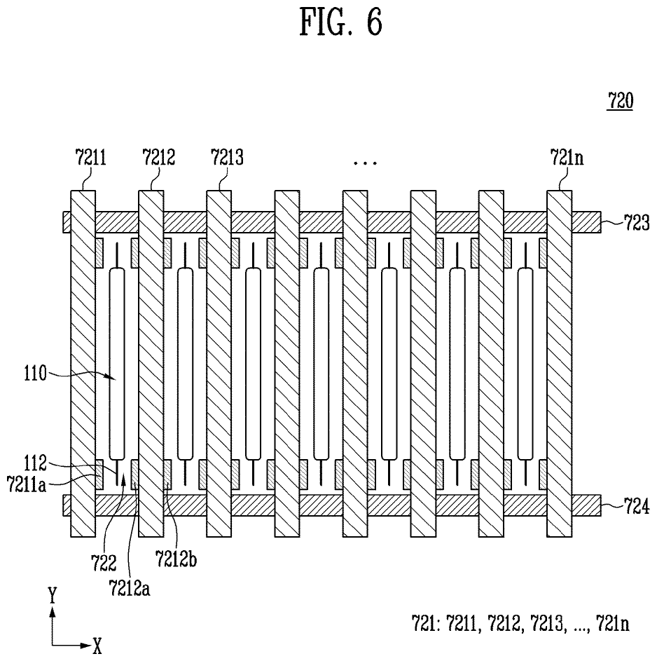

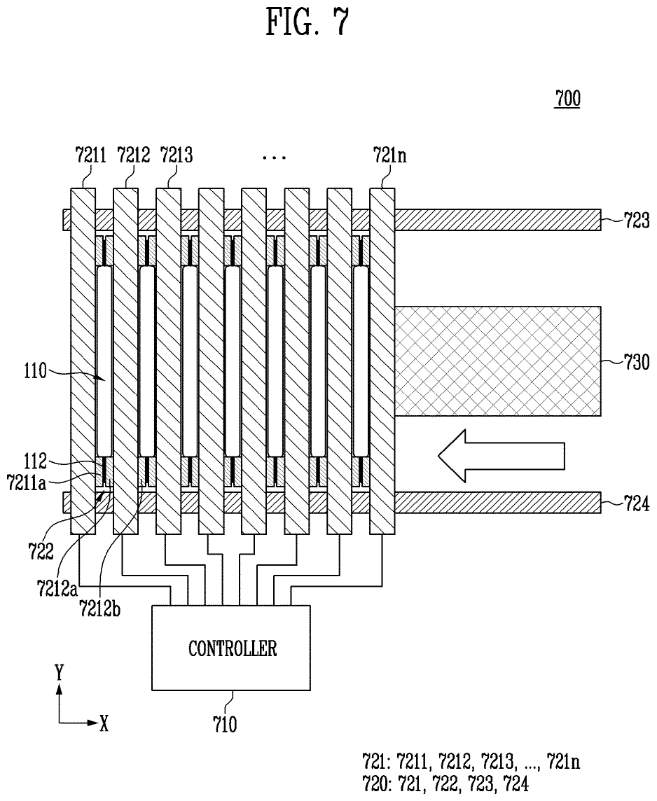

FIG. 5 is a block diagram illustrating an embodiment of a battery inspection system according to the present disclosure. FIG. 6 is a plan view illustrating an embodiment of a battery inspection system according to the present disclosure. FIG. 7 is a plan view illustrating an embodiment of a testing operation of a battery inspection system according to the present disclosure.

Referring to FIGS. 5 to 7, the battery inspection system 700 may include a controller 710, the charge/discharge unit 720, and a pressing unit 730.

The controller 710 may supply a charge and discharge (charge/discharge) current CDC to the charge/discharge unit 720. For example, the controller 710 may receive a control signal from the process control apparatus (100, see FIG. 3). Accordingly, the controller 710 may apply the charge/discharge current CDC of a predetermined magnitude to each of a plurality of channels 721 included in the charge/discharge unit 720. The charge/discharge current CDC may charge and/or discharge the plurality of battery cells 110 via the plurality of channels 721. However, this is merely an example and the present disclosure is not limited thereto. For example, the controller 710 may provide a control signal to the charge/discharge unit 720, and the charge/discharge unit 720 may charge and/or discharge the plurality of battery cells 110 based on the control signal.

The controller 710 may charge the plurality of battery cells 110. For example, the controller 710 may charge the plurality of battery cells 110 in a first charging method. According to an embodiment, the first charging method may be a Constant Current-Constant Voltage (CC-CV) charging method. For example, the controller 710 may apply the charge/discharge current CDC of a constant magnitude to the charge/discharge unit 720 for a predetermined period. Thereafter, the controller 710 may gradually decrease the magnitude of the charge/discharge current CDC, but may control a charging voltage at the plurality of battery cells 110 to be constant, and the plurality of battery cells 110 may be charged in the Constant Current-Constant Voltage (CC-CV) charging method.

According to another embodiment, the first charging method may be a Constant Current (CC) charging method. For example, the controller 710 may control a magnitude of the charge/discharge current CDC to be constant when charging the battery cells 110, and the plurality of battery cells 110 may be charged in the Constant Current (CC) charging method. The controller 710 may charge the plurality of battery cells 110 and might not charge the plurality of battery cells 110 for a predetermined period. According to an embodiment, the controller 710 may allow the plurality of battery cells 110 to rest for a predetermined period. For example, the controller 710 may charge the plurality of battery cells 110 in the first charging method and leave the plurality of battery cells 110 to stand for a predetermined period to stabilize the plurality of battery cells 110.

The controller 710 may charge the plurality of battery cells 110 in a second charging method. For example, the controller 710 may charge the plurality of battery cells 110 in the first charging method and then charge the plurality of battery cells 110 in the second charging method.

According to an embodiment, the second charging method may be a Constant Current (CC) charging method. For example, the controller 710 may control a magnitude of the charge/discharge current CDC to be constant when charging the battery cells 110 after a first charging, and the plurality of battery cells 110 may be charged in the Constant Current (CC) charging method.

According to another embodiment, the second charging method may be a Constant Current-Constant Voltage (CC-CV) charging method. For example, the controller 710 may apply the charge/discharge current CDC of a constant magnitude to the charge/discharge unit 720 for a predetermined period after the first charging. Thereafter, the controller 710 may gradually decrease the magnitude of the charge/discharge current CDC, but may control a charging voltage at the plurality of battery cells 110 to be constant, and the plurality of battery cells 110 may be charged in the Constant Current-Constant Voltage (CC-CV) charging method. According to an embodiment, the controller 710 may charge the plurality of battery cells 110 and stabilize the plurality of battery cells 110. For example, the controller 710 may recharge the plurality of battery cells 110 and stabilize the plurality of battery cells 110 for a predetermined first time period. In this example, the charging method in which the controller 710 recharges the plurality of battery cells 110 may be, but is not limited to, the second charging method.

According to an embodiment, the charge/discharge current CDC may be a direct current. However, the present disclosure is not limited thereto. For example, the charge/discharge current CDC may be an alternating current.

The charge/discharge unit 720 may include the plurality of channels 721 extending in one direction (e.g., Y-direction) and arranged to be spaced apart at predetermined intervals. The plurality of channels 721 may include a first channel 7211, a second channel 7212, a third channel 7213, . . . , an n-th channel 721n, where n is an integer of 4 or more. According to an embodiment, n may be, but is not limited to, 40.

Each of the plurality of channels 721 may include one or more connection terminals. For example, the first channel 7211 may include a first connection terminal 7211a. The second channel 7212 may include a second connection terminal 7212a and a third connection terminal 7212b. The first connection terminal 7211a and the second connection terminal 7212a may be disposed to face each other. The third connection terminal 7212b may be disposed symmetrically with the second connection terminal 7212a with respect to the second channel 7212. The first connection terminal 7211a may transfer the charge/discharge current CDC supplied to the first channel 7211 to the tab portion 112 of the battery cell 110. Accordingly, the battery cell 110 may be charged and/or discharged.

According to embodiments, the connection terminal may be implemented in the form of a Printed Circuit Board (PCB). However, the present disclosure is not limited thereto.

The plurality of charge/discharge rooms 722 may be spaces that accommodate the battery cells 110, each disposed between the plurality of channels 721. For example, the battery cell 110 may be disposed in the charge/discharge room 722, which is a space provided between the first channel 7211 and the second channel 7212.

The charge/discharge unit 720 may include a first frame 723 and a second frame 724. The first frame 723 and the second frame 724 may face each other in one direction (e.g., Y-direction). Opposite ends of each of the plurality of channels 721 may be disposed at the first frame 723 and the second frame 724, respectively.

Referring to FIG. 7, the pressing unit 730 may press the plurality of battery cells 110 and the plurality of channels 721 in one direction (e.g., direction opposite an X-direction). Accordingly, the tab portion 112 of each of the plurality of battery cells 110 may contact the connection terminal 7211a of the first channel 7211, which is one of the plurality of channels 721. The controller 710 may apply the charge/discharge current CDC to the plurality of battery cells 110 through the connection terminals of each of the plurality of channels 721. The shape of the pressing unit 730 shown in FIG. 7 is merely an example and is not limited as long as the pressing unit 730 can press the plurality of battery cells 110 and the plurality of channels 721 in one direction.

According to the present disclosure, the controller 710 may control charge/discharge timing of the plurality of battery cells 110. For example, the controller 710 may control supply timing of the charge/discharge current CDC to the charge/discharge unit 720. In other words, during first charging, the controller 710 may primarily charge the plurality of battery cells 110 in the first charging method by supplying the charge/discharge current CDC to the charge/discharge unit 720. The first charging method may be a Constant Current-Constant Voltage (CC-CV) charging method. However, the present disclosure is not limited thereto. For example, the first charging method may be a Constant Current (CC) charging method.

Thereafter, the controller 710 may suspend supply of the charge/discharge current CDC to the charge/discharge unit 720 for the predetermined first time period and stabilize the plurality of battery cells 110. After the controller 710 charges the battery cells 110 in the first charging method, the controller 710 may recharge the battery cells 110 in the second charging method. For example, after the first time period (or after the first time period and the second time period) for stabilizing the battery cells 110, the controller 710 may secondarily charge the battery cells 110 in the second charging method. According to an embodiment, the first time period and the second time period may each be more than 5 minutes, but are not limited thereto. According to an embodiment, the second charging method may be a Constant Current (CC) charging method. However, the second charging method is not limited thereto. For example, the second charging method may be a Constant Current-Constant Voltage (CC-CV) charging method.

The controller 710 may measure the Internal Resistance (IR) of the plurality of battery cells 110 during charging or discharging of the plurality of battery cells 110. For example, the controller 710 may receive measurement data MD from the charge/discharge unit 720. The controller 710 may calculate IR measurement values of the battery cells 110 based on the measurement data MD. The measurement data MD may include information regarding IR values measured at each of the battery cells 110 (or tab portion 112) when the battery cells 110 are charged or discharged.

As an example, the controller 710 may measure the IR of the battery cells 110 while recharging the battery cells 110 in the second charging method after charging the battery cells 110 in the first charging method. For example, the controller 710 may calculate the IR measurement values of the battery cells 110 based on the measurement data MD obtained during recharging of the battery cells 110. The first charging method may be a Constant Current-Constant Voltage (CC-CV) charging method, and the second charging method may be a Constant Current (CC) charging method. According to an embodiment, the controller 710 may calculate the IR measurement values of each of the plurality of battery cells 110 using (end-of-charge voltage-start-of-charge voltage)/the charge/discharge current CDC.

In another example, the controller 710 may measure the IR of the battery cells 110 while discharging the battery cells 110 after charging the battery cells 110 in the first charging method and then recharging the battery cells 110 in the second charging method. For example, the controller 710 may calculate the IR measurement values of the battery cells 110 based on the measurement data MD obtained during discharging of the battery cells 110. The first charging method may be a Constant Current (CC) charging method, and the second charging method may be a Constant Current-Constant Voltage (CC-CV) charging method. According to an embodiment, the controller 710 may calculate the IR measurement value of each of the plurality of battery cells 110 using (|start-of-charge voltage−end-of-charge voltage or voltage after a lapse of n seconds|)/|the charge/discharge current CDC|.

According to an embodiment, the controller 710 may measure the IR of the battery cells 110 in a Direct Current Internal Resistance (DC-IR) method in which the Internal Resistance (IR) of the battery cells 110 is measured by applying a direct current via the charge/discharge unit 720. However, the present disclosure is not limited thereto.

The controller 710 may calculate a representative value of the IR measurement values of each of the battery cells 110. For example, the controller 710 may calculate an average value of the IR measurement values as the representative value. However, the present disclosure is not limited thereto. According to an embodiment, the controller 710 may calculate a median value of the IR measurement values as the representative value.

The controller 710 may compare each of the IR measurement values with the representative value of the IR measurement values to determine whether each of the battery cells 110 is defective. According to an embodiment, the controller 710 may calculate a difference value between each of the IR measurement values and the representative value of the IR measurement values. The controller 710 may determine whether each of the battery cells 110 is defective based on the difference value. For example, the controller 710 may calculate a difference value between the IR measurement value of the battery cell 110 disposed between the first channel 7211 and the second channel 7212 and the representative value of the IR measurement values. When the difference value exceeds a predetermined reference value, the controller 710 may determine that the corresponding battery cell 110 is open-circuited (or cracked). In other words, the controller 710 may determine whether each of the battery cells 110 is defective by determining whether the tab portions (111 and 112, see FIG. 1) of the corresponding battery cell 110 are open-circuited. However, this is merely an example, and a manner of determining whether the battery cell 110 is defective is not limited thereto.

The difference value compared with the predetermined reference value may be an absolute value of a value obtained by subtracting the representative value of the IR measurement values from one of the IR measurement values.

According to an embodiment of the present disclosure, the battery inspection system 700 may stabilize the plurality of battery cells 110 after primarily charging the plurality of battery cells 110 and before secondarily charging the plurality of battery cells 110. For example, the controller 710 may stabilize the battery cells 110 for a predetermined first time period, then measure the IR of the battery cells 110 while recharging the battery cells 110. Accordingly, the accuracy of the IR value of the battery cell 110 measured by the battery inspection system 700 may be relatively improved, and the reliability of whether the battery cell 110 is defective as determined by the battery inspection system 700 may be improved.

According to an embodiment of the present disclosure, the reliability of a manufacturing process of the battery cell 110 may be improved. For example, the battery inspection system 700 may determine whether the battery cell 110 (or the tab portion 112) is open-circuited during the manufacturing process of the battery cell 110 without dismantling the battery cell 110. Accordingly, the time and/or cost required for the manufacturing process of the battery cell 110 may be relatively reduced, and the yield of the manufacturing process of the battery cell 110 may also be relatively improved.

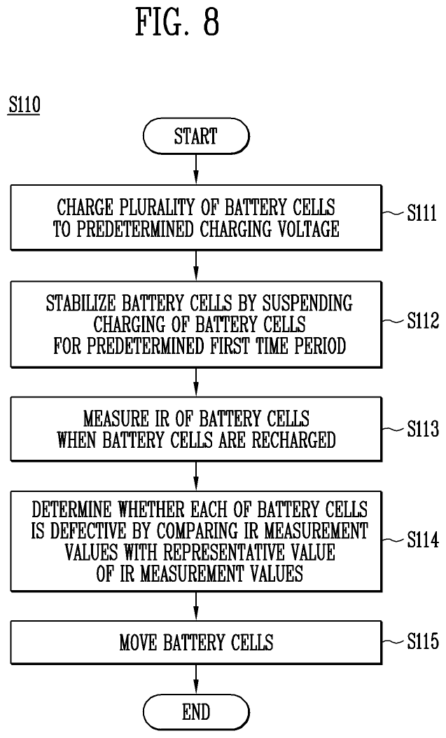

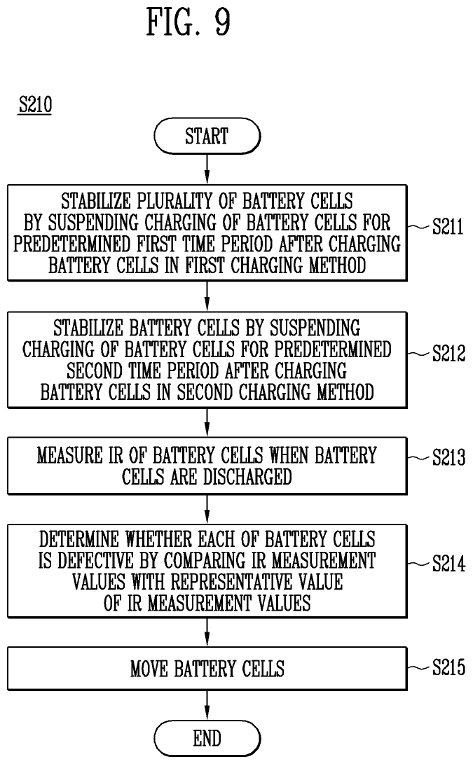

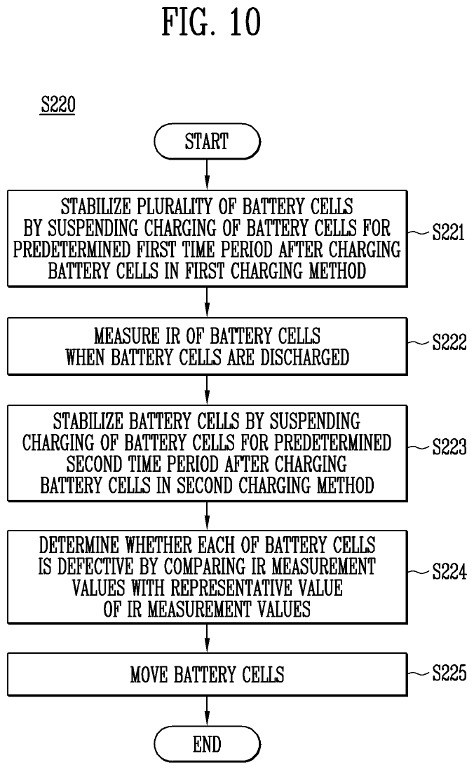

FIG. 8 is a flowchart illustrating an embodiment of a battery cell inspection method according to the present disclosure. The flowchart illustrated in FIG. 8 is described above with reference to FIGS. 5 to 7, and therefore, any repetitive detailed description is omitted. Similarly, with respect to FIGS. 9 and 10 to be described below, any repetitive detailed description is also omitted.

Referring to FIGS. 5 to 8, an inspection method S110 of the battery cell 110 according to an embodiment includes first charging S111 for charging the plurality of battery cells 110 to a predetermined charging voltage, stabilizing S112 the plurality of battery cells 110 by suspending the charging of the plurality of battery cells 110 for a predetermined first time period, measuring S113 Internal Resistance (IR) of the plurality of battery cells 110 when the plurality of battery cells 110 are recharged, and determining S114 whether each of the battery cells 110 is defective by comparing IR measurement values with a representative value of the IR measurement values.

The inspection method S110 of the battery cell 110 may further include moving S115 the plurality of battery cells 110. For example, in the inspection method S110 of the battery cell 110, the plurality of battery cells 110 may be moved to the degassing apparatus (900, see FIG. 3) after determining S114 whether each of the battery cells 110 is defective by comparing the IR measurement values with the representative value of the IR measurement values. Accordingly, the degassing process (P900, see FIG. 2) may be performed only on the battery cells 110 that are moved to the degassing apparatus 900. For example, the battery inspection system (700, see FIG. 3) may determine which battery cell 110 among the battery cells 110 is open-circuited through comparing the IR measurement values with the representative value of the IR measurement values of S114. Thereafter, the battery manufacturing system (1000, see FIG. 3) may move only those battery cells 110 that are not open-circuited such that the degassing process P900 may be performed only on those battery cells 110. Accordingly, the battery manufacturing system 1000 may perform the degassing process P900 excluding the open-circuited battery cells 110, and the yield of the manufacturing process of the battery cell 110 may be relatively improved.

According to an embodiment, the plurality of battery cells 110 may be moved by the charge/discharge transfer member (600, see FIG. 4). However, the present disclosure is not limited thereto, and the battery cells 110 may be moved by a transfer member having a different shape.

Determining S114 whether each of the battery cells 110 is defective by comparing the IR measurement values with the representative value of the IR measurement values may include calculating a difference value between one of the IR measurement values and the representative value, comparing the difference value with a predetermined reference value, and determining whether the battery cells 110 are open-circuited.

Further, measuring S113 the Internal Resistance (IR) of the plurality of battery cells 110 when the plurality of battery cells 110 are recharged may be performed after stabilizing S112 the plurality of battery cells 110 by suspending the charging of the plurality of battery cells 110 for the predetermined first time period.

FIG. 9 is a flowchart illustrating an example of another embodiment of a battery cell inspection method according to the present disclosure.

Specifically, FIG. 8 relates to the inspection method S110 of the battery cell 110 in which the battery inspection system 700 determines whether the battery cell 110 is open-circuited by measuring the IR of the battery cell 110 while charging the plurality of battery cells 110, whereas FIG. 9 relates to an inspection method S210 of the battery cell 110 in which the battery inspection system 700 determine whether the battery cell 110 is open-circuited by measuring the IR of the battery cell 110 while discharging the plurality of battery cells 110.

Referring to FIGS. 5 to 9, the inspection method S210 of the battery cell 110 for the battery inspection system 700 according to another embodiment includes stabilizing S211 the plurality of battery cells 110 by suspending the charging of the battery cells 110 for a predetermined first time period after charging the plurality of battery cells 110 in a first charging method, stabilizing S212 the battery cells 110 by suspending the charging of the battery cells 110 for a predetermined second time period after charging the battery cells 110 in a second charging method, measuring S213 the IR of the battery cells 110 when the battery cells 110 are discharged, and determining S214 whether each of the battery cells 110 is defective by comparing IR measurement values with a representative value of the IR measurement values. In this regard, S214 of FIG. 9 may be described in the same manner as S114 of FIG. 8.

In addition, the inspection method S210 of the battery cell 110 may further include moving S215 the plurality of battery cells 110. For example, in the inspection method S210 of the battery cell 110 the plurality of battery cells 110 may be moved to the degassing apparatus (900, see FIG. 3) after determining S214 whether each of the battery cells 110 is defective by comparing the IR measurement values with the representative value of the IR measurement values. Accordingly, the degassing process (P900, see FIG. 2) may be performed only on the battery cells 110 that are moved to the degassing apparatus 900. For example, the battery inspection system (700, see FIG. 3) may determine which battery cell 110 among the battery cells 110 is open-circuited through comparing the IR measurement values with the representative value of the IR measurement values of S214. Thereafter, the battery manufacturing system (1000, see FIG. 3) may move only those battery cells 110 that are not open-circuited such that the degassing process P900 may be performed only on those battery cells 110. Accordingly, the battery manufacturing system 1000 may perform the degassing process P900 excluding the open-circuited battery cells 110, and the yield of the manufacturing process of the battery cell 110 may be relatively improved.

FIG. 10 is a flowchart illustrating another example of another embodiment of a battery cell inspection method according to the present disclosure.

Specifically, FIG. 9 relates to the inspection method S210 of the battery cell 110 in which the battery inspection system 700 measures the IR of the battery cell 110 while discharging the battery cells 110 and measures the IR of the battery cells 110 after sequentially charging the plurality of battery cells 110 in the first charging method and the second charging method, whereas FIG. 10 relates to an inspection method S220 of the battery cell 110 in which the battery inspection system 700 primarily charges the battery cells 110, and then discharges the battery cells 110 and measures the IR of the battery cells 110.

Referring to FIGS. 5 to 10, the inspection method S220 of the battery cell 110 for the battery inspection system 700 according to another embodiment includes stabilizing S221 the plurality of battery cells 110 by suspending the charging of the plurality of battery cells 110 for a predetermined first time period after charging the battery cells 110 in a first charging method, measuring S222 the IR of the battery cells 110 when the battery cells 110 are discharged, stabilizing S223 the battery cells 110 by suspending the charging of the battery cells 110 for a predetermined second time period after charging the battery cells 110 in a second charging method, and determining S224 whether each of the battery cells 110 is defective by comparing IR measurement values with a representative value of the IR measurement values.

In this regard, S221, S222, S223, and S224 of FIG. 10 may be described in the same manner as S211, S213, S212, and S214 of FIG. 9, respectively. Hereinafter, any repetitive detailed description is omitted.

According to an embodiment of the present disclosure, measuring S222 the IR of the battery cells 110 when the battery cells 110 are discharged may be performed after stabilizing S221 the plurality of battery cells 110 by suspending the charging of the plurality battery cells 110 for the predetermined first time period after charging the battery cells 110 in the first charging method.

According to an embodiment, in the inspection method S220 of the battery cell 110 for the battery inspection system 700, stabilizing S223 the battery cells 110 by suspending the charging of the battery cells 110 for the predetermined second time period after charging the battery cells 110 in the second charging method. However, the present disclosure is not limited thereto.

The present disclosure may be implemented in various forms, and the scope of the present disclosure is not limited to the embodiments described above. Accordingly, any modified embodiments that include elements of the appended claims of the present disclosure should be construed as falling within the scope of the present disclosure.

What is claimed is:

1. A battery cell inspection method for a battery inspection system which includes a pressing unit configured to press a plurality of battery cells and a charge and discharge (charge/discharge) unit configured to charge and discharge the plurality of battery cells, the method comprising:
first charging in which the plurality of battery cells are charged to a predetermined charging voltage in a first charging method via the charge/discharge unit;
stabilizing the plurality of battery cells by suspending charging of the plurality of battery cells to the charging voltage via the charge/discharge unit for a predetermined first time period;
measuring Internal Resistance (IR) of the plurality of battery cells when the plurality of battery cells are recharged in a second charging method via the charge/discharge unit; and
determining whether each of the plurality of battery cells is defective by comparing IR measurement values with a representative value of the IR measurement values.

2. The method of claim 1, wherein determining whether each of the plurality of battery cells is defective includes determining whether the plurality of battery cells are open-circuited by calculating a difference value between the representative value and one of the IR measurement values and comparing the difference value with a predetermined reference value.

3. The method of claim 1, wherein measuring the IR of the plurality of battery cells is performed after stabilizing the plurality of battery cells for the predetermined first time period.

4. The method of claim 1, further comprising moving the plurality of battery cells after determining whether each of the plurality of battery cells is defective by comparing the IR measurement values with the representative value of the IR measurement values,
wherein in moving the plurality of battery cells, the plurality of battery cells are moved to a degassing apparatus configured to perform degassing on the plurality of battery cells.

5. The method of claim 1, wherein in measuring the IR of the plurality of battery cells, the IR is measured in a Direct Current Internal Resistance (DC-IR) method in which the IR is measured by applying a direct current via the charge/discharge unit.

6. The method of claim 1, wherein the first charging method is a Constant Current-Constant Voltage (CC-CV) charging method, and
wherein the second charging method is a Constant Current (CC) charging method.

7. A battery cell inspection method for a battery inspection system which includes a pressing unit configured to press a plurality of battery cells and a charge and discharge (charge/discharge) unit configured to charge and discharge the plurality of battery cells, the method comprising:
stabilizing the plurality of battery cells by suspending charging of the plurality of battery cells for a predetermined first time period after charging the plurality of battery cells in a first charging method via the charge/discharge unit;
stabilizing the plurality of battery cells by suspending charging of the plurality of battery cells for a predetermined second time period after charging the plurality of battery cells in a second charging method via the charge/discharge unit;
measuring Internal Resistance (IR) of the plurality of battery cells when the plurality of battery cells are discharged via the charge/discharge unit; and
determining whether each of the plurality of battery cells is defective by comparing IR measurement values with a representative value of the IR measurement values.

8. The method of claim 7, wherein determining whether each of the plurality of battery cells is defective includes determining whether the plurality of battery cells are open-circuited by calculating a difference value between the representative value and one of the IR measurement values and comparing the difference value with a predetermined reference value.

9. The method of claim 7, wherein the first charging method is a Constant Current (CC) charging method, and
wherein the second charging method is a Constant Current-Constant Voltage (CC-CV) charging method.

10. The method of claim 7, wherein the plurality of battery cells are discharged after stabilizing the plurality of battery cells by suspending the charging of the plurality of battery cells for the second time period.

11. The method of claim 7, wherein the plurality of battery cells are discharged after stabilizing the plurality of battery cells by suspending the charging of the plurality of battery cells for the first time period, and before stabilizing the plurality of battery cells by suspending the charging of the plurality of battery cells for the second time period.

12. The method of claim 7, further comprising moving the plurality of battery cells after determining whether each of the plurality of battery cells is defective by comparing the IR measurement values with the representative value of the IR measurement values,
wherein in moving the plurality of battery cells, the plurality of battery cells are moved to a degassing apparatus configured to perform degassing on the plurality of battery cells.

13. A battery inspection system comprising:
a charge and discharge (charge/discharge) room configured to respectively accommodate a plurality of battery cells;
a plurality of channels including connection terminals electrically coupled to the plurality of battery cells;
a pressing unit configured to press the plurality of channels and the plurality of battery cells in one direction; and
a controller configured to control a current or a voltage applied to the plurality of battery cells via the connection terminals,
wherein the controller measures Internal Resistance (IR) of the plurality of battery cells when the plurality of battery cells are charged or discharged via the plurality of channels.

14. The battery inspection system of claim 13, wherein the controller is configured to determine whether the plurality of battery cells are defective by calculating a difference value between IR measurement values and a representative value of the IR measurement values and comparing the difference value with a predetermined reference value.

15. The battery inspection system of claim 14, wherein the representative value is an average value of the IR measurement values of the plurality of battery cells.

16. The battery inspection system of claim 13, wherein the controller is configured to charge the plurality of battery cells to a predetermined charging voltage in a first charging method via the plurality of channels, and charge the plurality of battery cells in a second charging method after a predetermined first time period.

17. The battery inspection system of claim 16, wherein the controller measures the IR of the plurality of battery cells while the plurality of battery cells are charged in the second charging method.

18. The battery inspection system of claim 17, wherein the first charging method is a Constant Current-Constant Voltage (CC-CV) charging method, and the second charging method is a Constant Current (CC) charging method.

19. The battery inspection system of claim 16, wherein the controller charges the plurality of battery cells in the second charging method, and measures the IR of the plurality of battery cells while the plurality of battery cells are discharged after a predetermined second time period.

20. The battery inspection system of claim 19, wherein the first charging method is a Constant Current (CC) charging method, and the second charging method is a Constant Current-Constant Voltage (CC-CV) charging method.
